(19) United States
(12) Patent Application Publication
(10) Pub. No.: US 2001/0054484 A1
(43) Pub. Date: Dec. 27, 2001

(54) Plasma processor, cluster tool, and method of controlling plasma

(76) Inventor: Mitsuaki Komino, Nakano-ku (JP)

Correspondence Address: Pillsbury Madison & Sutro LLP, Intellectual Property Group, Ninth Floor, 1100 New York Avenue, NW, Washington, DC, 20005-3918, US

(21) Appl. No.: 09/739,623

(22) Filed: Dec. 20, 2000

Related U.S. Application Data
(63) Continuation of application No. PCT/JP00/07459, filed on Oct. 25, 2000.

(30) Foreign Application Priority Data
Nov. 22, 1999 (JP) 11-331496

(51) Int. Cl. C23C 16/00; H01L 21/3065

(52) U.S. Cl. 156/345; 118/723 R

(57) ABSTRACT

While maintaining transferability of a subject to be processed, plasma is made uniform. The plasma processor comprises a member for generating plasma and a member for controlling axial symmetry of the generated plasma. The axial symmetry control member comprises pin conductors movable in Z direction and an insert type gate valve. By approaching the pin conductor to the insert type gate valve and by arranging the pin conductors along an inside shape of the insert gate valve, even in the portion of the insert gate valve, an electric current can be flowed similarly with the portion of the chamber wall. Thereby, current flow can be made uniform.

### TECHNICAL FIELD

The present invention relates to a plasma processor, a cluster tool and a method of controlling plasma, and is preferably applicable in manufacturing semiconductor devices, liquid crystal display devices or plasma display devices.

### BACKGROUND ART

In the existing semiconductor manufacturing process, a plasma processor is used for depositing on a semiconductor wafer or performing fine patterning. In performing the processing in a plasma processor, semiconductor wafers are necessary to be taken in and out of the plasma processor. Accordingly, in the existing plasma processor, an opening is formed in a case (chamber wall) of the plasma processor, therethrough the semiconductor wafers being taken in and out. After the semiconductor wafers are transferred into the plasma processor, a gate valve disposed at the opening is closed to provide the inside of the plasma processor with hermetic vacuum isolation.

However, in the existing plasma processor, upon closing the gate valve, due to the discrepancy between shapes of an end of the gate valve and an inner wall of the case, a concave is caused at an insertion portion of the gate valve. Into a space of the concave, plasma enters. Accordingly, axial symmetry of the plasma collapses to deteriorate deposition and processing properties of the semiconductor wafers. Further, at the concave, deposition occurs, deposition products peeling off to cause particle contamination.

Further, in the existing plasma processor, in order to open and close the gate valve, the gate valve is in an electrically floating state. Accordingly, at the gate valve, a current flow is disturbed to cause nonuniformity of the current flow in the chamber wall. As a result, axial symmetry collapses to deteriorate deposition properties on the wafer and processing properties thereof during plasma processing.

The present invention is carried out in considering the above circumstances. An object of the present invention is to provide a plasma processor, a cluster tool and a method for controlling plasma that, while maintaining transferability of a subject to be processed, are capable of making the plasma uniform.

### DISCLOSURE OF THE INVENTION

To solve the above problems, a plasma processor involving the present invention comprises a portion for generating plasma and member for controlling axial symmetry of the generated plasma.

By comprising the axial symmetry control member, the axial symmetry of the generated plasma can be controlled. Thereby, while maintaining transferability of a subject to be processed, the plasma can be made uniform to result in an improvement of deposition properties and processing properties of wafers due to the plasma processing.

In addition, a plasma processor involving the present invention comprises a chamber wall, a radio frequency power source, a susceptor, a processing gas introducing portion, an electric power supply, a gate valve and a conductive member. Here, the chamber wall has an opening for taking in and out a subject to be processed and constitutes a processing chamber therein. The radio frequency power source generates radio frequency electric power. The susceptor is disposed in the processing chamber inside of the chamber wall and supports the subject to be processed that is carried into the processing chamber through the opening. The processing gas introducing portion is disposed to the processing chamber inside of the chamber wall and introduces a processing gas into the processing chamber. The electric power supply is disposed to the processing chamber inside of the chamber wall and generates plasma out of the processing gas by supplying the generated radio frequency power to the introduced processing gas. The gate valve clogs the opening and prevents the generated plasma from intruding into the opening. The conductive member provides a current path at the gate valve or in the neighborhood thereof.

The gate valve is disposed to clog the opening of the chamber wall and to prevent the plasma from intruding in the opening thereof. Further, at the gate valve or in the neighborhood thereof there is conductive member to be a current path. Therewith, uniformity of the generated plasma can be improved. Accordingly, while maintaining transferability of the subject to be processed, depositability and processability of the wafer due to the plasma processing can be improved.

Further, a cluster tool involving the present invention, comprises a portion of performing the plasma processing of a subject to be processed and a portion of carrying the subject to be processed to the plasma processing portion. Here, the aforementioned cluster tool comprises a member for suppressing the plasma from intruding into the route of carrying the subject to be processed and a conductive member for providing a current path in the route of carrying the subject to be processed.

In the route of carrying the subject to be processed, a member for suppressing the plasma intrusion is disposed. Thereby, the uniformity of the generated plasma can be improved, accordingly, while maintaining transferability of the subject to be processed, deposit ability and processability of the wafer due to the plasma processing can be improved.

A method of controlling plasma involving the present invention comprises the steps of carrying a subject to be processed into a plasma processor, of forming a plasma processing space, of forming an electric current path, and of performing plasma processing of the subject to be processed. Here, the step of forming a plasma processing space is performed so as to ensure symmetry of an inside shape of the plasma processor therein the subject to be processed is transferred. The step of forming an electric current path in the plasma processing space is performed so as to make uniform the current in the plasma processor. The step of performing plasma processing of the subject to be processed is performed in the plasma processor having the plasma processing space therein the current path is established.

In the plasma processor, the plasma processing space is formed so as to ensure the symmetry of the inside shape thereof, further in the plasma processing space, the current path is established so that the current in the plasma processor is made uniform. Since the plasma processing is performed in such a plasma processor, the uniformity of the generated plasma can be improved, accordingly, while maintaining the transferability of the subject to be processed, depositability and processability of the wafers due to the plasma processing can be improved.

### BRIEF DESCRIPTION OF THE DRAWINGS

FIG. 1 is a plan view showing one example of a configuration of a cluster tool applied in the present invention.

FIG. 2A is a side view showing a configuration of process and transfer modules involving one embodiment of the present invention,

FIG. 2B being a plan view seen from an A-A surface of FIG. 2A.

FIG. 3A is a side view showing in enlargement a portion of a gate valve 37 of FIG. 2,

FIG. 3B being a side view showing another embodiment of the gate valve 37 of FIG. 3A.

FIG. 4A is a diagram showing a skin effect,

FIG. 4B being a diagram showing the relationship between frequency and skin depth.

### THE BEST MODE FOR IMPLEMENTING THE INVENTION

As a preferable mode for performing the present invention, an axial symmetry control member can comprise a space providing member and a conductive member. The space-providing member provides a space shape in the route of carrying a subject to be processed. The conductive member provides a current path in the route of carrying the subject to be processed.

Thereby, without impairing the transferability of the subject to be processed, an intruding route of the plasma can be controlled and the uniformity of the current can be ensured. As a result, without impairing operability during the plasma processing, the plasma processing can be performed with accuracy.

Further, conductive member, based on an skin effect that is a radio frequency characteristic of a current that flows the conductor, can provide a thickness from a surface thereof.

Thereby, a current path can be established with only a surface portion of the conductor, and device load in providing the current path can be lowered.

As a preferable mode for performing the present invention, the gate valve comprises a convex engaging into a thickness of the chamber wall at the opening. In the convex, a surface shape of a side facing the processing chamber is formed continuous with an inner surface shape of the chamber wall.

The conductive member can be a pin-like conductor arranged along a processing chamber surface side of the gate valve.

The conductive member can be an inflatable conductive film that electrically connects the gate valve and the chamber wall.

In the following, one embodiment of the present invention will be described with reference to the drawings.

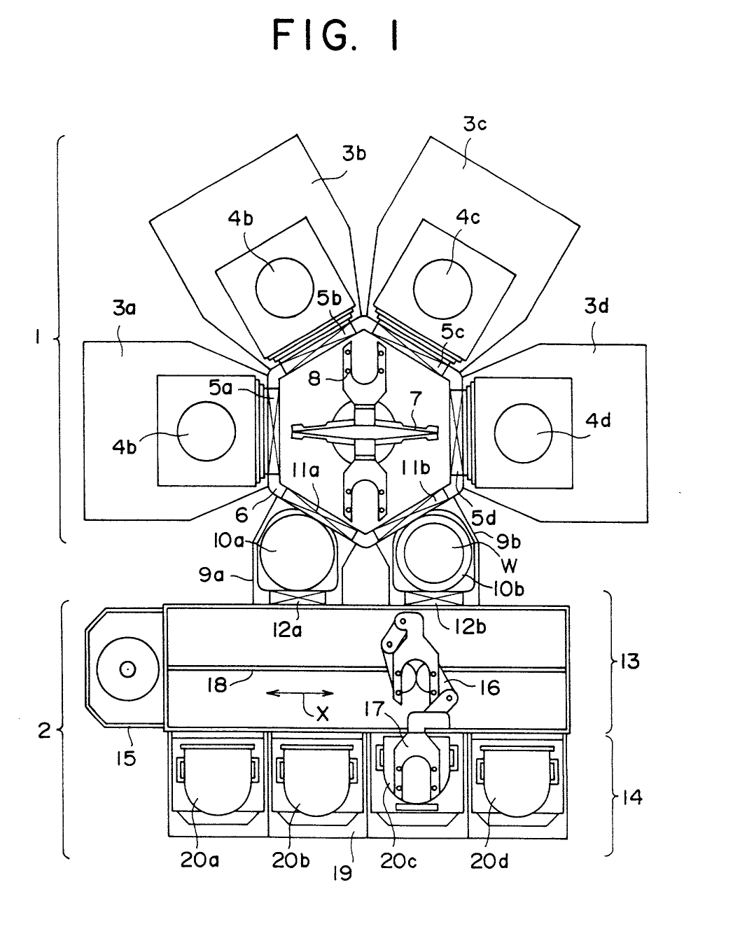

FIG. 1 is a plan view showing one example of a schematic configuration of a cluster tool in which the present invention is applied. In FIG. 1, a cluster tool comprises a processing system 1 and a carrying system 2. Here, the processing system 1 performs various kinds of processings such as deposition, diffusion, etching or the like to a wafer W as a subject to be processed. The carrying system 2 takes in and out the wafers with respect to the processing system 1.

To the processing system 1, processing chambers 3a to 3d for performing various kinds of processings and a transfer chamber 6 that can be evacuated are provided, the processing chambers 3a to 3d communicating with the transfer chamber 6 through gate valves 5a to 5d.

To the carrying system 2, a carrying stage 13 for moving a carrying arm 16 and a cassette stage 14 for supporting carrier cassettes 20a to 20d are provided. At one end of the carrying stage 13, an orienter 15 is disposed as an orientation alignment device for performing alignment of the wafer W.

The processing system 1 communicates with the carrying system 2 through load lock chambers 9a and 9b that can be evacuated. The load lock chambers 9a and 9b communicate with the transfer chamber 6 through gate valves 11a and 11b and with the carrying stage 13 through gate valves 12a and 12b.

To the processing chambers 3a to 3d, susceptors 4a to 4d for supporting the wafers W are provided respectively to perform various kinds of processings such as deposition, diffusion, etching or the like to the wafers W.

In the transfer chamber 6, a transfer arm 7 constituted freely bendable and rotatable and an end effecter 8 for holding the wafer W is disposed. The transfer arm 7 gives and takes the wafer W between the processing chambers 3a to 3d each and the load lock chambers 9a to 9b.

To the load lock chamber 9a and 9b, wafer susceptors 10a and 10b and a vacuum pump not shown in the figure are disposed. The transfer arm 7 carries the wafers W supported on the wafer susceptors 10a and 10b into the processing chambers 3a to 3d. Thereby, without releasing the inside of the processing system 1 in the air, the wafers can be given and taken between the processing system 1 and the carrying system 2.

A cassette susceptor 19 is provided to the cassette stage 14, on the cassette susceptor 19 the carrier cassettes 20a to 20d being disposed. In the carrier cassette 20a to 20d each, for instance at most 25 pieces of wafers W can be accommodated disposed in equidistance in multi stages.

To the carrying stage 13, the carrying arm 16 for carrying to give and take the wafers and a guide rail 18 extending along a length direction at a center portion of the carrying stage 13 are disposed. To the guide rail 18, the carrying arm 16 furnished with the end effector 17 is supported movable.

In the cluster tool, the load lock chambers 9a and 9b, the transfer chamber 6 and the processing chambers 3a to 3d each can be independently evacuated. In the order of from the load lock chambers 9a and 9b to the transfer chamber 6 to the processing chambers 3a to 3d, the degree of vacuum can be increased. In carrying the wafers W accommodated in the carrier cassettes 20a to 20d each into the processing chambers 3a to 3d, first the wafers W accommodated in the carrier cassettes 20a to 20d each are carried into the load lock chambers 9a and 9b by the carrying arm 16. Next, the wafers W carried into the load lock chambers 9a and 9b are carried into the transfer chamber 6 by the transfer arm 7. The wafers W carried in the transfer chamber 6 are carried in the processing chambers 3a to 3d by the use of the transfer arm 7.

Thereby, even in taking the wafers W in and out of the processing chambers 3a to 3d, the insides of the processing chambers 3a to 3d can be prevented from exposing to the air. That is, the insides of the processing chambers 3a to 3d can be prevented from contaminating due to the air and particle in the air can be prevented from intruding into the processing chambers 3a to 3d. Accordingly, high accuracy processing can be realized.

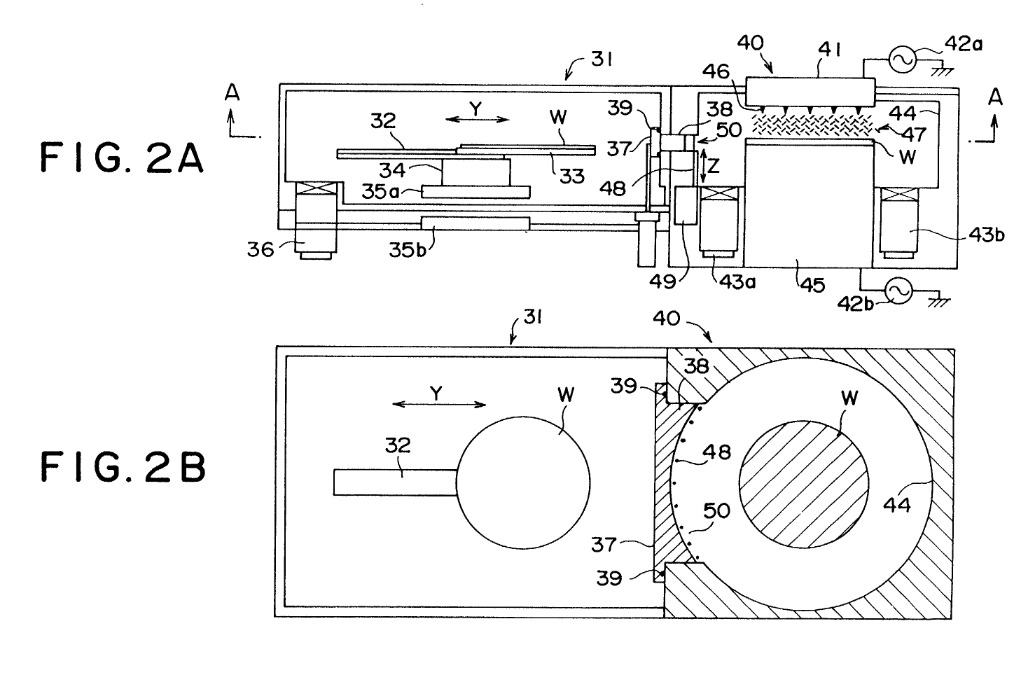

FIG. 2A is a side view showing a schematic configuration of a process module and a carrying module involving one embodiment of the present invention, FIG. 2B being a plan view seen from an A-A surface of FIG. 2A. In FIG. 2, to a carrying module 31, a transfer arm 32, an end effector 33 for holding a wafer W, a crawler type vacuum robot 34, sliders 35a and 35b, and a Nude type turbo molecular pump 36 are provided. The transfer arm 32 is constituted freely bendable and rotatable. The sliders 35a and 35b implement noncontact carry and noncontact power supply. The Nude type turbo molecular pump 36 evacuates the insides of the carrying module 31.

To the process module 40, a cylindrical gas shower head/upper electrode 41 and a cylindrical susceptor/lower electrode 45 are disposed faced to each other. In addition to these, Nude type turbo molecular pumps 43a and 43b for evacuating the inside of the process module 40, pin-like conductors 48 and driving means 49 are disposed, a space where the plasma processing is carried out being surrounded by the chamber wall 44. The gas shower head/upper electrode 41, connected to a radio frequency power source 42a, supplies the gas 46 into the process module 40 and converts the gas 46 into plasma. Here, so as to convert efficiently the gas 46 into the plasma to generate dense plasma 47, frequency of the radio frequency power source 42a can be set at for instance 13.56 MHz.

The susceptor/lower electrode 45, connected to the radio frequency power source 42b, supports the wafers W carried in the process module 40 and efficiently draws ions or electrons in the plasma 47 into the susceptor/lower electrode 45. Here, in order to draw in efficiently the ions or electrons in the plasma 47, frequency of the radio frequency power source 42b can be set at for instance 800 kHz.

The chamber wall 44 is formed cylindrical in conformity with the cylindrical susceptor/lower electrode 45, and the chamber wall 44 can confine the plasma 47 generated between the gas shower head/upper electrode 41 and the cylindrical susceptor/lower electrode 45. Thereby, the axial symmetry of the plasma 47 can be maintained. Further, the chamber wall 44 is electrically conductive and forms a return circuit of a radio frequency current generated due to the plasma processing.

Furthermore, in the chamber wall 44, an opening 50 is disposed, through the opening 50 the transfer arm 32 can be inserted into the process module 40. Thereby, the wafers W carried in from the carrying module 31 can be disposed on the susceptor/lower electrode 45, and the wafers after processing can be carried out of on the susceptor/lower electrode 45.

In the opening 50 of the chamber wall 44, an insert type gate valve 37 is disposed, the closing of the insert type gate valve 37 enabling to close the opening 50. Further, to the insert type gate valve 37, a convex 38 is disposed. The shape of the convex 38 can be formed, when closing the insert type gate valve 37, to follow approximately a cylindrical surface of the inside of the chamber wall 44. Thereby, the plasma 47 is prevented from intruding into the space of the opening 50 to enable to maintain the axial symmetry thereof 47. As a result, the deposition or the etching of the wafers W can be prevented from becoming nonuniform and since the deposition in the space of the opening 50 is prevented from occurring, the deposition products are prevented from peeling off to cause particle contamination.

To the insert type gate valve 37, an O-ring 39 is provided, thereby air-tightness in the process module 40 during evacuation can be improved.

The pin-like conductors 48 are disposed in arrangement in the neighborhood of the convex 38 of the insert type gate valve 37. The high frequency current generated due to the plasma processing can be flowed along the pin-like conductors 48. Thereby, in the opening 50 where the insert type gate valve 37 is inserted, nonuniformity of the high frequency current flow can be cancelled to result in maintaining the axial symmetry of the plasma 47.

Here, the pin-like conductors 48 are preferably arranged so that the current flow in the chamber wall 44 becomes uniform. Accordingly, the pin-like conductors 48 are preferably arranged to approach the insert type gate valve 37 as much as possible and to follow the inside shape of the insert type gate valve 37. Further, a direction of the pin-like conductors 48 is preferable to be directed in Z direction. Thereby, the current flow at the opening 50 can be made equal with that of the chamber wall 44.

The driving means 49 moves the pin-like conductors 48 in Z direction. That is, in giving and taking the wafers W between the process module 31 and the carrying module 40, the pin-like conductors 48 are pulled in by the driving means 49 to prevent from disturbing the giving and taking of the wafers W. Further, when carrying out the plasma processing of the wafers W, the pin-like conductors are projected from the driving means 49. Thereby, ends of the pin-like conductors 48 reach the upper level of the convex 38 of the insert type gate valve 37 and potential of the pin-like conductors 48 is made equal with that of the chamber wall 44.

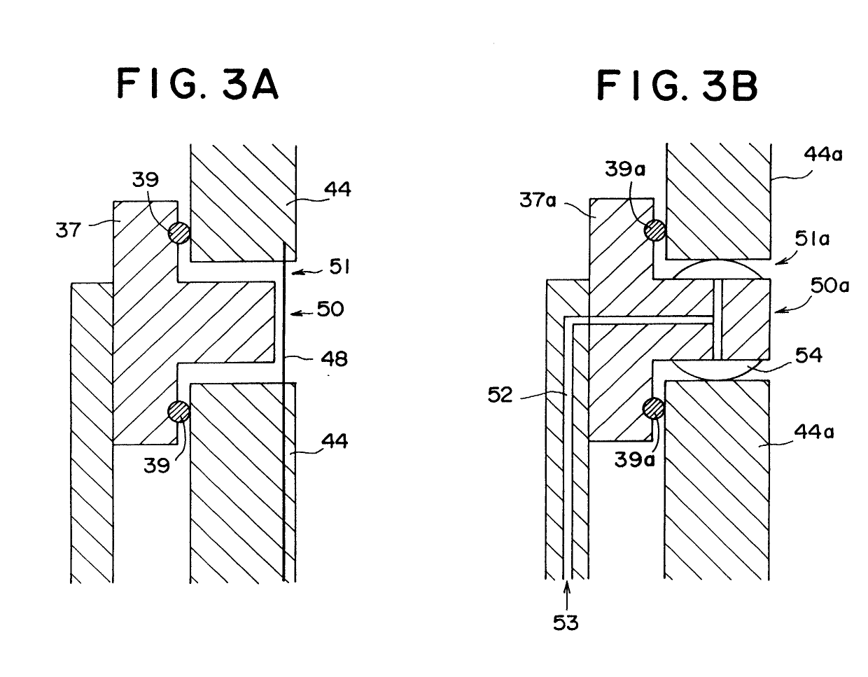

FIG. 3A is a side view showing in enlargement a portion of the gate valve 37 of FIG. 2. In FIG. 3A, the gate valve 37 is inserted into the opening 50 of the chamber wall 44 or pulled out of the opening 50 of the chamber wall 44. Accordingly, between the gate valve 37 and the chamber wall 44, a gap 51 is disposed to make electrically floated therebetween when the gate valve 37 is inserted into the opening 50. Accordingly, in carrying out the plasma processing, the pin-like conductors 48 are projected and inserted into the upper portion of the chamber wall 44 to form a current path in the opening 50.

Next, the movements of the process module 31 and the carrying module 41 of FIG. 2 will be explained.

First, in carrying the wafer W held by the end effector 33 to the process module 40, the pin-like conductors 48 are pulled into the driving means 49 and the gate valve 37 is pulled out of the opening 50 to ensure a carrying path of the wafer W. Then, the transfer arm 32 is moved in Y direction to dispose the wafer W on the susceptor/lower electrode 45 disposed in the chamber. Upon disposing the wafer W on the susceptor/lower electrode 45, the gate valve 37 is inserted into the opening 50. The pin-like conductors 48 are then projected in Z direction and thrust in the upper portion of the chamber wall 44 to form the current path at the opening 50. While evacuating with Nude type turbo molecular pumps 43a and 43b, the gas 46 is introduced into the chamber and the radio frequency power is applied to the gas shower head/upper electrode 41 and the susceptor/lower electrode 45. Thereby, the plasma 47 is generated to perform the plasma processing of the wafer W. At that time, due to the convex 38 disposed on the gate valve 37, the plasma 47 can be suppressed from intruding into the opening 50, and due to the pin-like conductors 48, the current path at the opening 50 can be ensured. Thus, the current flowing the chamber wall 44 can be made uniform. As a result, the axial symmetry of the plasma 47 generated in the chamber can be obtained to result in an improvement of the uniformity of the plasma processing to the wafer W.

Here, when the plasma 47 is generated by use of the radio frequency, the radio frequency current flows a surface of material but hardly flows the insides of the material. Accordingly, in the case of the radio frequency, since the current hardly flows the insides of the pin-like conductor 48, even when the pin-like conductor 48 is made larger in diameter exceeding a certain degree, there is no difference in effect.

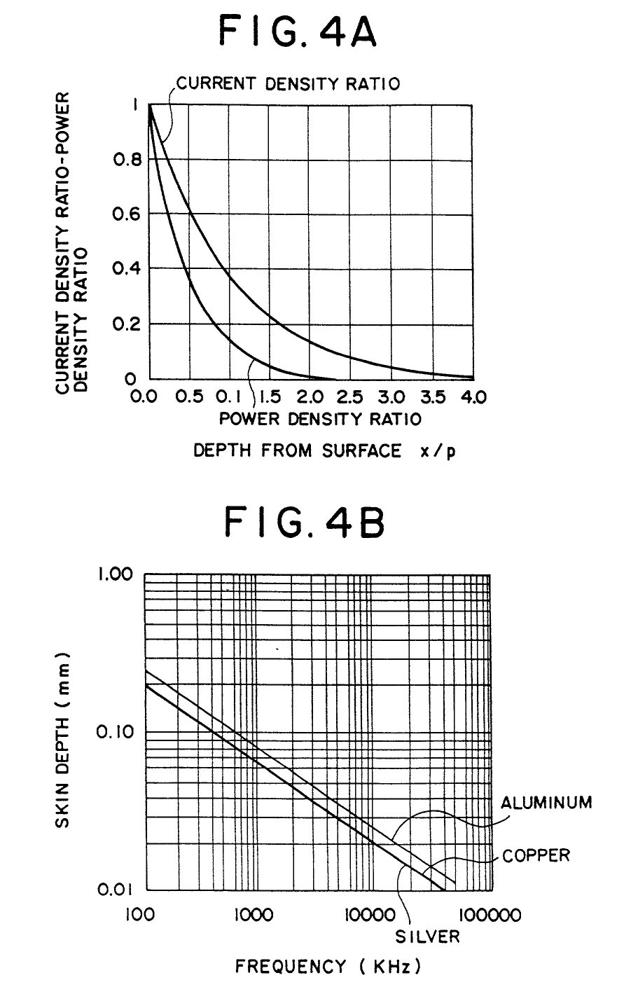

FIG. 4A is a diagram showing a skin effect. Here, the skin effect is given by the following equation.

Ix=I₀exp(−x/p)exp(jx/p)

Ix: a current value (A) at a point of x (m) from a surface toward a center

I₀: a current value (A) on a surface of cylindrical metallic body

p: a depth (m) where the value of current decreases to 1/e of that in the surface.

FIG. 4B is a diagram showing the relationship between skin depth and frequency. Here, the skin depth is given by the following equation.

p=√(ρ×10⁷)/{2π√(μᵣf)}

μᵣ: permittivity

ρ(+106·•cm): volume resistivity

f (Hz): frequency

Therefrom, when the plasma is generated under a bias of for instance 800 kHz and the pin-like conductors 48 are made of aluminum, it is found that the high frequency current flows within the range of approximately 0.09 mm from the surface. Accordingly, even if the diameter of the pin-like conductor 48 were set at approximately 0.09 mm or more, the effect would be hardly different from that when the diameter is set at 0.09 mm. Accordingly, by setting the diameter of the pin-like conductors 48 at approximately 0.09 mm, while ensuring the current path equivalent with the chamber wall 44, the pin-like conductors 48 can be downsized and light-weighted. As a result, load on the driving device 49 when the pin-like conductors 48 are moved in Z direction can be lowered.

In the aforementioned embodiment, in order to ensure the current path of the convex 38 of the gate valve 37, a configuration in arranging the pin-like conductors 48 in the neighborhood of the convex 38 of the gate valve 37 is explained. However, other methods than this can be adopted.

FIG. 3B is a side view showing another embodiment of the gate valve 37 of FIG. 3A. In FIG. 3B, for the gate valve 37a, a conductive diaphragm 54 is disposed and a path 52 for sending air 53 to the diaphragm 54 is disposed. Here, in order to ensure the conductivity of the diaphragm 54, other than a method of forming the diaphragm 54 per se by conductive material, a surface of the diaphragm 54 can be made conductive.

Even in this case, by taking the aforementioned skin depth into consideration, the thickness of the conductive material or the conductive film can be provided.

In performing the plasma processing, the gate valve 37a is inserted into the opening 50a. Then, the air 53 is sent into the diaphragm 54 to expand thereby the diaphragm 54 closing the gap 51a and coming into contact with the chamber wall 44a. Thereby, the gate valve 37 comes into electrical contact with the chamber wall 44.

On the other hand, when the gate valve 37a is pulled out of the opening 50a, the air 53 sent into the diaphragm 54 is drawn out to contract the diaphragm 54, thereby the diaphragm 54 and the chamber wall 44a ceasing to be in contact.

Thereby, the plasma can be suppressed from intruding into the gap 51a and the current path at the opening 50a can be ensured to result in an improvement of the uniformity in the plasma processing. Into the path 52 for expanding the diaphragm 54, other than gas such as the air 53, liquid such as oil may be flowed.

In the example of FIG. 3B, the diaphragm 54 and the path 52 are disposed on the gate valve 37a side. However, the diaphragm 54 and the path 52 may be disposed on the chamber wall side.

Other than the aforementioned method, for instance the convex 38 of the gate valve 37 may be formed of bellows covered by a conductive film and after closing the gate valve 37, the bellows are inflated. By getting the bellows into contact with the chamber wall 44, the current path at the convex 38 of the gate valve 37 may be ensured.

In the aforementioned example, a parallel-plate plasma CVD apparatus is taken up as an example. However, the present invention can be applied in a magnetron plasma CVD apparatus, an ECR (Electron Cyclotron Resonance) plasma CVD apparatus utilizing high ionization plasma generated by electron cyclotron resonance or the like. Further, the present invention may be applied in a plasma etching apparatus, a reactive ion etching apparatus, a reactive ion beam etching apparatus or the like.

As explained above, according to the present invention, the shape of the end surface of the gate valve can be made equal with that of the inside of the chamber wall. Accordingly, since the plasma can be prevented from intruding into the concave generated at an insertion portion of the gate valve, the symmetry of the plasma can be maintained to result in an improvement of deposit ability and processability of the wafers due to the plasma processing.

When performing the plasma processing of the wafers, at the gate valve and in the neighborhood thereof, the current path can be formed to enable to make uniform the current flow. When the wafers are taken in and out, the current path generated at the gate valve and in the neighborhood thereof can be removed to enable to ensure the carrying path of the wafers.

Industrial Applicability

A plasma processor involving the present invention and a cluster tool thereof can be used in manufacturing semiconductor devices or liquid crystal display devices. Accordingly, in manufacturing apparatuses for manufacturing semiconductor devices and liquid crystal display devices, the present invention can be performed. A method for controlling plasma involving the present invention can be used when manufacturing semiconductor devices and liquid crystal display devices. Accordingly, the present invention can be performed when semiconductor devices and liquid crystal display devices are manufactured.

1. A plasma processor processing a subject to be processed, comprising:
a portion for generating plasma; and
member for controlling axial symmetry of the generated plasma.

2. The plasma processor as set forth in claim 1:
wherein the member for controlling axial symmetry comprises;
member for providing a space shape in a carrying path of the subject to be processed; and
conductive member for providing an electrical path in the carrying path of the subject to be processed.

3. The plasma processor as set forth in claim 2:
wherein the conductive member, based on a skin effect that is a radio frequency characteristic of an electric current flowing a conductor, has a thickness from a surface thereof.

4. A plasma processor, comprising:
a chamber wall having an opening for taking in and out a subject to be processed and constituting a processing chamber inside of the chamber wall;
a radio frequency power source for generating radio frequency electric power;
a susceptor, disposed in the processing chamber inside of the chamber wall, for supporting the subject to be processed carried from the opening into the processing chamber;
a gas introducing portion, disposed in the processing chamber inside of the chamber wall, for introducing a processing gas into the processing chamber;
an electric power supplying portion, disposed in the processing chamber inside of the chamber wall, for converting the introduced processing gas into plasma by supplying the generated radio frequency power to the introduced processing gas;
a gate valve for closing the opening and for preventing the generated plasma from intruding into the opening; and
conductive member providing an electric current path at the gate valve or in a neighborhood thereof.

5. The plasma processor as set forth in claim 4:
wherein the gate valve comprises a convex engaging a thickness of the chamber wall at the opening, in the convex a surface shape on a side facing the processing chamber being continuous with an inner surface shape of the chamber wall.

6. The plasma processor as set forth in claim 4:
the conductive member is pin conductor arranged along the processing chamber surface side of the gate valve.

7. The plasma processor as set forth in claim 4:
wherein the conductive member is an inflatable conductive film for connecting electrically the gate valve and the chamber wall.

8. A cluster tool having a portion for plasma processing a subject to be processed and a portion for carrying the subject to be processed into the processing portion, the cluster tool comprising:
plasma intrusion suppressive member for suppressing plasma from intruding into a carrying path of the subject to be processed; and
conductive member for providing an electric current path in the carrying path of the subject to be processed.

9. A method for controlling plasma, comprising the steps of:
carrying a subject to be processed into a plasma processor;
forming a plasma processing space so as to ensure symmetry of an inside shape of the plasma processor into which the subject to be processed is carried;
forming, in the plasma processing space, an electric current path for making uniform an electric current of the plasma processor; and
plasma processing the subject to be processed in the plasma processor having the plasma processing space where the electric current path is formed.
